(19) United States
(12) Patent Application Publication
(10) Pub. No.: US 2026/0110759 A1
(43) Pub. Date: Apr. 23, 2026

(54) MAGNETORESISTIVE ELEMENT AND MAGNETIC SENSOR COMPRISING SAME

(71) Applicant: TDK CORPORATION, Tokyo (JP)

(72) Inventor: Takafumi KOBAYASHI, Tokyo (JP)

(73) Assignee: TDK CORPORATION, Tokyo (JP)

(21) Appl. No.: 19/362,138

(22) Filed: Oct. 17, 2025

(30) Foreign Application Priority Data
Oct. 23, 2024 (JP) 2024-186636

(51) Int. Cl. G01R 33/09; H10N 50/10

(52) U.S. Cl. CPC G01R 33/093; H10N 50/10

(57) ABSTRACT

A magnetoresistive element (1) comprises a magnetic free layer (6) whose magnetization direction changes upon application of an external magnetic field and in which magnetization has a vortex shape in a state in which an external magnetic field is not applied, a magnetic pinned layer (4) whose magnetization direction is pinned with respect to an external magnetic field, and a nonmagnetic layer (5) located between the magnetic free layer (6) and the magnetic pinned layer (4). The magnetic free layer (6), the magnetic pinned layer (4), and the nonmagnetic layer (5) are arranged in the Z-direction. The nonmagnetic layer (5) has a boundary surface (51) that is in contact with the magnetic free layer (6), and a portion of the magnetic free layer (6) is outside an outer periphery (53) of the boundary surface (51) as viewed from the Z-direction.

### FIELD

This application claims the benefit of Japanese Priority Patent Application No. 2024-186636 filed on October 23, 2024, the entire contents of which are incorporated herein by reference.

The present disclosure relates to a magnetoresistive element and a magnetic sensor comprising same.

### BACKGROUND

JP6355706B describes a magnetoresistive element comprising a magnetic free layer magnetized in a vortex shape in a state in which an external magnetic field is not applied (zero magnetic field state). The center of the vortex shape (core) is at the center of the magnetic free layer in the zero magnetic field state but the vortex shape moves toward the periphery of the magnetic free layer when an external magnetic field is applied.

### SUMMARY

The object of the present disclosure is to provide a magnetoresistive element having good linearity of output with respect to an external magnetic field and comprising a magnetic free layer that is magnetized in a vortex shape in the absence of an external magnetic field and whose magnetization direction changes upon application of an external magnetic field.

A magnetoresistive element of the present disclosure comprises a magnetic free layer that is magnetized in a vortex shape in a state in which an external magnetic field is not applied and whose magnetization direction changes upon application of an external magnetic field, a magnetic pinned layer whose magnetization direction is pinned with respect to an external magnetic field, and a nonmagnetic layer located between the magnetic free layer and the magnetic pinned layer, the magnetic free layer, the magnetic pinned layer, and the nonmagnetic layer being aligned in a first direction. The nonmagnetic layer has a boundary surface in contact with the magnetic free layer, and a portion of the magnetic free layer is outside the periphery of the boundary surface as viewed in the first direction.

The above and other objects, features, and advantages of the present application will become apparent from the following detailed description with reference to the accompanying drawings which illustrate the present application.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIGS. 1A and 1B are a schematic cross-sectional view and a schematic plan view of a magnetoresistive element according to a first example embodiment.

FIG. 2 is a schematic cross-sectional view of a magnetoresistive element of a comparative example.

FIG. 3 is a conceptual drawing showing a magnetic curve and magnetization states of a magnetic free layer.

FIGS. 4A-4E are schematic cross-sectional views of a magnetoresistive elements of variations of the first example embodiment.

FIGS. 5A and 5B are schematic cross-sectional views of a magnetoresistive element according to a second example embodiment.

FIGS. 6A and 6B are a schematic cross-sectional view and a schematic plan view of a magnetoresistive element according to a third example embodiment.

FIGS. 7A-7D are schematic cross-sectional views and schematic plan views of a magnetoresistive element according to a fourth example embodiment.

FIGS. 8A-8D are schematic plan views of magnetic free layers of a magnetoresistive element according to a fifth example embodiment.

FIG. 9 is a schematic view of a magnetic sensor according to a sixth example embodiment.

FIGS. 10A-10C are graphs showing the relationships between the diameter of a boundary surface of a nonmagnetic layer, resistance of a magnetoresistive element, and output of a magnetic sensor.

FIGS. 11A-11C are graphs showing the relationships between a diameter of a boundary surface of a nonmagnetic layer, sensitivity, and linearity of a magnetic sensor.

FIG. 12 is a graph showing the relationship between the diameter and thickness of a magnetic free layer and the generation rate of a vortex shape.

### DETAILED DESCRIPTION

In the following, some example embodiments and modification examples of the technology are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

In the related art, when an external magnetic field increases and magnetization of a magnetic free layer approaches saturation, the vortex shape of the magnetic free layer disappears, and the entire layer becomes magnetized in the same direction. However, when the vortex shape of the magnetic free layer disappears, the magnetic moment of the magnetic free layer changes discontinuously, and this change reduces linearity of the output of a magnetoresistive element.

Example embodiments of the present disclosure will be described below with reference to the drawings. In the following description and drawings, a first direction is referred to as the Z-direction, a second direction is referred to as the X-direction, and a third direction is referred to as the Y-direction. The Z-direction refers to the stacking direction of laminated body 2, and the X- and Y-directions refer to the in-plane direction of each layer of laminated body 2. The X-, Y-, and Z-directions are mutually orthogonal. The direction from substrate 3 to laminated body 2 is called the +Z-direction, and the direction from laminated body 2 to substrate 3 is called the –Z-direction. When magnetic pinned layer 4 is magnetized in a direction orthogonal to the Z-direction, the magnetization direction of magnetic pinned layer 4 is referred to as the X-direction. In the drawings, an arrow in magnetic pinned layer 4 indicates the magnetization direction of magnetic pinned layer 4.

### First Example Embodiment

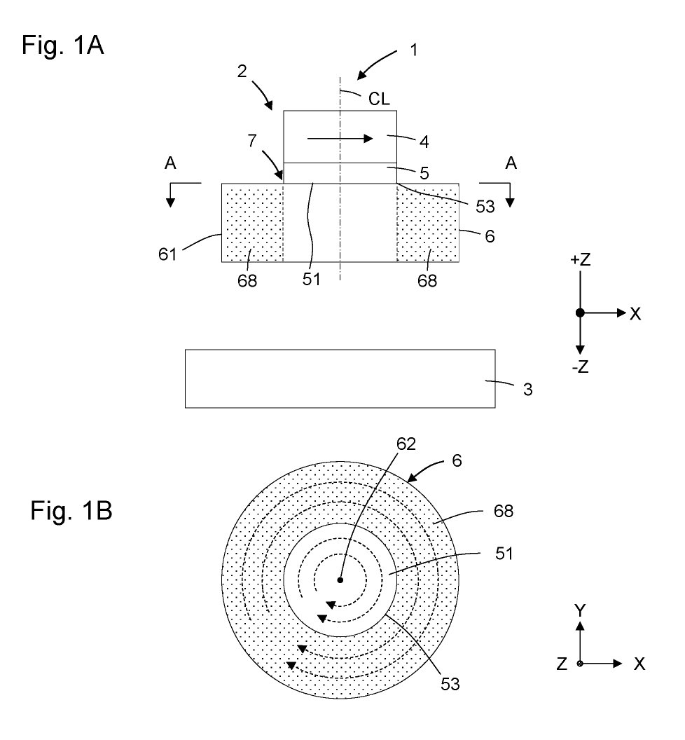

FIG. 1A shows a cross-sectional view of magnetoresistive element 1 according to a first example embodiment of the present disclosure. FIG. 1B shows a cross-sectional view along line A-A of FIG. 1A. Magnetoresistive element 1 may comprise laminated body 2 and silicon substrate 3. Laminated body 2 and substrate 3 may be arranged in the Z-direction. Although not shown in the drawing, other layers such as electrode layers may be provided between laminated body 2 and substrate 3, and laminated body 2 may be separated from substrate 3.

Laminated body 2 may comprise magnetic pinned layer 4, nonmagnetic layer 5, and magnetic free layer 6. These layers 4–6 may be arranged in the order of magnetic free layer 6, nonmagnetic layer 5, and magnetic pinned layer 4 in the +Z-direction. Magnetic free layer 6 may be located between substrate 3 and magnetic pinned layer 4 in the Z-direction. Magnetic free layer 6 and nonmagnetic layer 5 may be in contact with each other, and nonmagnetic layer 5 and magnetic pinned layer 4 may be in contact with each other. Magnetic free layer 6, nonmagnetic layer 5, and magnetic pinned layer 4 may be cylinders or disks having common Z-directional central axis CL. Side surface 61 of magnetic free layer 6 may be continuously formed in the Z-direction and may not change discontinuously. In other words, no steps may be provided on side surface 61 of magnetic free layer 6.

Magnetic pinned layer 4 may be a magnetic layer whose magnetization direction is pinned in the X-direction with respect to an external magnetic field. Magnetic pinned layer 4 may be formed from CoFeB or the like. Although not shown in the drawings, magnetic pinned layer 4 may have a structure in which an inner magnetic pinned layer in contact with nonmagnetic layer 5, an intermediate layer made from ruthenium, iridium, or the like, and an outer magnetic pinned layer are arranged in that order in the +Z-direction. In this structure, the inner and outer magnetic pinned layers may be magnetized in directions opposite to each other by synthetic antiferromagnetic coupling through the intermediate layer, whereby the leakage magnetic field applied from magnetic pinned layer 4 to magnetic free layer 6 can be suppressed. Magnetic pinned layer 4 may comprise an antiferromagnetic layer that is in contact with the outer magnetic pinned layer in the +Z-direction. Since the magnetization direction of the outer magnetic pinned layer may be firmly pinned by the antiferromagnetic layer, the magnetization direction of the outer magnetic pinned layer in the zero magnetic field state may be easily stabilized.

Magnetic free layer 6 may be a magnetic layer whose magnetization direction changes with respect to an external magnetic field. Magnetic free layer 6 may be formed from, for example, CoFe, CoFeB, or NiFe. The magnetization direction of magnetic free layer 6 (shown as dashed lines in FIG. 1B) may have a vortex shape when viewed from the Z-direction in the zero magnetic field state, and the magnetization direction changes when an external magnetic field is applied. The magnetization state of magnetic free layer 6 in the zero magnetic field state may depend on the balance between the exchange energy and the magnetostatic energy of magnetic free layer 6. In general, a vortex-shaped magnetization state is more likely to occur when the saturation magnetization is large. In the zero magnetic field state, the center of the vortex shape, called core 62, may be located at the center of magnetic free layer 6, and the magnetization direction may describe concentric circles around core 62. In general, this magnetic free layer 6 may have less hysteresis than magnetic free layer 6 in which the magnetization direction is oriented in one direction in the zero magnetic field state.

Nonmagnetic layer 5 may be located between magnetic free layer 6 and magnetic pinned layer 4. Nonmagnetic layer 5 may comprise an insulating layer such as MgO or Al₂O₃. Magnetoresistive element 1 of the present example embodiment may act as a tunnel magnetoresistive element (TMR element). Nonmagnetic layer 5 may comprise a nonmagnetic metal layer such as copper or silver. In this case, magnetoresistive element 1 may act as a giant magnetoresistive element (GMR element). TMR elements may tend to have higher output than GMR elements.

The diameter of magnetic free layer 6 may be larger than the diameters of magnetic pinned layer 4 and nonmagnetic layer 5, and step 7 may be formed between nonmagnetic layer 5 and magnetic free layer 6. Nonmagnetic layer 5 may have circular boundary surface 51 that is in contact with magnetic free layer 6, and portion 68 of magnetic free layer 6 may be outside periphery 53 of boundary surface 51 when viewed in the Z-direction. In other words, the entire area of boundary surface 51 of nonmagnetic layer 5 may be inside the outer periphery of magnetic free layer 6 when viewed in the Z-direction. Outer periphery of magnetic free layer 6 means the outer periphery of a portion projected in the Z-direction of magnetic free layer 6. Boundary surface 51 of nonmagnetic layer 5 may be inside the projected portion of magnetic free layer 6 and may not overlap the outer periphery of the projected portion.

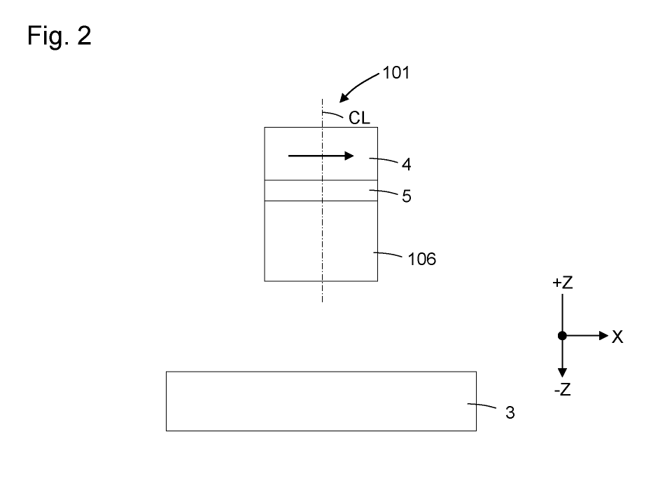

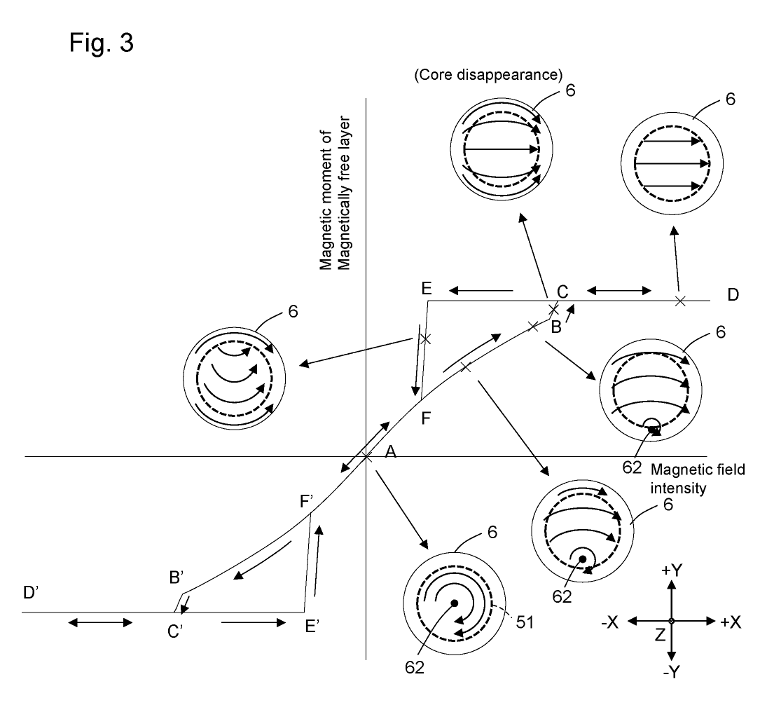

The effect of this structure will be explained by contrasting it with a comparative example. FIG. 2 shows a cross-sectional view of magnetoresistive element 101 of a comparative example. In the comparative example, magnetic free layer 106, nonmagnetic layer 5, and magnetic pinned layer 4 may be cylinders or disks having the same diameters and common Z-directional central axis CL. FIG. 3 shows a magnetization curve of disk-shaped magnetic free layer 6. FIG. 3 schematically shows the magnetization states of magnetic free layer 6 at several positions on the magnetization curve, specifically, the X-direction component of the magnetic moment of magnetic free layer 6 normalized by the total amount of magnetic moment. For convenience, the upward direction of the drawing is the +Y-direction and the downward direction of the drawing is the –Y-direction.

At point A, which is the zero magnetic field state, the magnetization of magnetic free layer 6 may have a vortex shape and core 62 may be present in the center. When a magnetic field in the +X-direction is applied, the magnetic moment of magnetic free layer 6 may increase. Magnetic free layer 6 as a whole may be magnetized in the +X-direction and core 62 may move in the –Y-direction. Linearity between the magnetic field intensity and the magnetic moment may generally be maintained, but linearity may decrease as core 62 moves in the –Y-direction. Upon reaching point B, a jump in magnetic moment may occur and the magnetic moment may increase discontinuously and may become saturated (point D). The jump in magnetic moment may occur when core 62 disappears (point C). When the magnetic field intensity is reduced from point D, the magnetic moment decreases rapidly at point E and core 62 appears (point F). The case is the same when a magnetic field is applied in the –X-direction. Points B' to F' correspond to points B to F. The magnetization of magnetic free layer 6 at points B' to F' may have a shape that is rotated 180° around the center of magnetic free layer 6 from the magnetization at points B to F. In FIG. 3, a single line indicates the magnetization between points F and F', but in fact, two different paths may be taken depending on the application direction of the magnetic field. However, in magnetic free layer 6, which is magnetized in a vortex shape in the zero magnetic field state, the two paths are close together and the hysteresis is smaller than in other structures of the magnetic free layer.

In the comparative example, when a magnetic field is applied that is greater than the magnetic field strength at point B, linearity of the signal may be reduced due to the jump in the magnetic moment. Therefore, for practical purposes, magnetoresistive element 101 of the comparative example must be limited to use between B and B'. This constraint may limit the range that can be used as the output of the magnetic sensor and limit the magnetic field strength that can be detected. However, the sudden jump in magnetic moment may be caused by a difference in distortion of magnetization near the outer edge of magnetic free layer 6 before and after core 62 disappears and becomes a single magnetic domain due to the external magnetic field. The inner region of magnetic free layer 6 may be less affected by the distortion of magnetization. The magnetization direction may generally be oriented in the +X direction as the magnetic field intensity increases. Change in magnetization state may be continuous. In this example embodiment, the inner region of magnetic free layer 6, i.e., the region that faces boundary surface 51 and that is enclosed in the Z-direction by the dashed lines in the drawings may be used as the effective portion of magnetic free layer 6. Since the disappearance of core 62 of magnetic free layer 6 may occur outside the dashed lines, the jump in magnetic moment may have no significant effect on the output voltage of magnetoresistive element 1. As a result, even if the magnetic field intensity is increased up to the D and D' points, linearity of the output voltage signal may not decrease significantly, and a larger magnetic field may be detected than in the comparative example.

Although not shown in the drawing, the above description clearly indicates that boundary surface 51 of nonmagnetic layer 5 is not limited to a circular shape. Boundary surface 51 of nonmagnetic layer 5 may be, for example, oval or polygonal, and the center of boundary surface 51 may be eccentric from the center of magnetic free layer 6 provided that portion 68 of magnetic free layer 6 is outside outer periphery 53 of boundary surface 51 of nonmagnetic layer 5 with magnetic free layer 6 when viewed in the Z-direction.

To form magnetoresistive element 1 of the present example embodiment, films that will become magnetic free layer 6, nonmagnetic layer 5, and magnetic pinned layer 4 are formed, following which a resist mask is formed on the film which will become magnetic pinned layer 4. Next, the portions of the films that are not covered by the resist mask are removed by etching to form nonmagnetic layer 5 and magnetic pinned layer 4 in a predetermined shape. The resist mask is then removed, and contaminants deposited on the surface of magnetic pinned layer 4 are removed by reverse sputtering. In this process, thin nonmagnetic layer 5 may be protected by magnetic pinned layer 4, and this protection may reduce the possibility of degradation of nonmagnetic layer 5 due to the reverse sputtering. Since the thickness of magnetic pinned layer 4 may be greater than that of nonmagnetic layer 5, the effect of degradation during reverse sputtering may be limited. A protective film such as tantalum may also be deposited on the film that will become magnetic pinned layer 4, and this protective film may protect magnetic pinned layer 4 during reverse sputtering.

### Variations of the First Example Embodiment

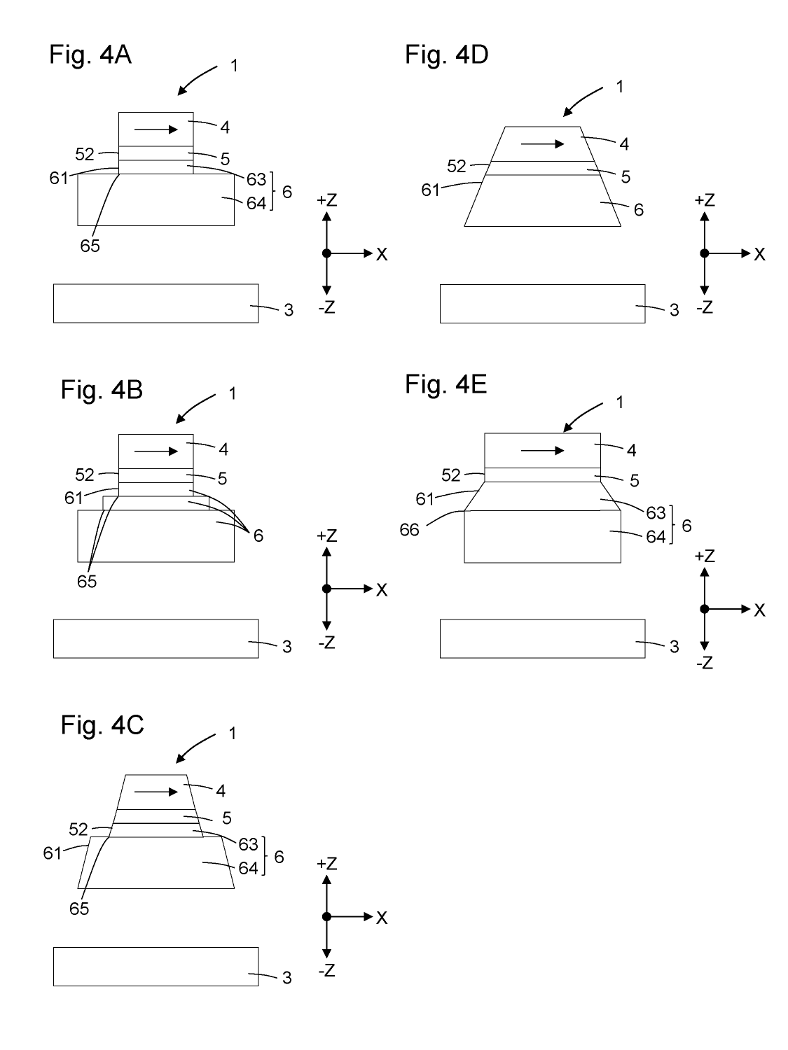

When viewed from the Z-direction, magnetic free layer 6 may have various shapes as long as portion 68 of magnetic free layer 6 is outside outer periphery 53 of boundary surface 51 of nonmagnetic layer 5 with magnetic free layer 6. FIG. 4 shows a cross-sectional view of magnetoresistive element 1 of some variations of the first example embodiment. In these variations, side surface 52 of nonmagnetic layer 5 and side surface 61 of magnetic free layer 6 may be continuously connected, and no steps may be formed between nonmagnetic layer 5 and magnetic free layer 6. In these variations, the diameter of magnetic free layer 6 may vary in the Z-direction, but the average diameter of magnetic free layer 6 in the Z-direction may be larger than the average diameter of nonmagnetic layer 5 and magnetic pinned layer 4 in the Z-direction.

In the first variation shown in FIG. 4A, magnetic free layer 6 may comprise first portion 63 and second portion 64. First portion 63 and second portion 64 may have a coaxial disk or cylindrical shape and may be aligned in the Z-direction. First portion 63 and second portion 64 may be formed of the same material or of different materials. First portion 63 may have the same diameter as nonmagnetic layer 5 and may be in contact with nonmagnetic layer 5. Second portion 64 may be in contact with first portion 63 and may be located on the side of first portion 63 that is opposite to nonmagnetic layer 5. The diameter of first portion 63 may be smaller than the diameter of second portion 64, and one step 65 may be formed on side surface 61 of magnetic free layer 6. The thickness (the Z-direction dimension) of first portion 63 may be smaller than the thickness (the Z-direction dimension) of second portion 64. This provision suppresses the effect of the antimagnetic field generated at the edge of first portion 63 and improves linearity of output. The magnetization direction of second portion 64 may have a vortex shape in the zero magnetic field state. Since first portion 63 has a smaller volume than second portion 64, it may be affected by the magnetization of second portion 64 and may be magnetized in the same way as second portion 64. Therefore, this variation may exhibit the same effects as the first example embodiment. To form magnetoresistive element 1 of this variation, the films that will become magnetic free layer 6, nonmagnetic layer 5, and magnetic pinned layer 4 may be deposited, and then a portion of each of these films removed to form magnetic free layer 6, nonmagnetic layer 5, and magnetic pinned layer 4 in a predetermined shape.

In the second variation shown in FIG. 4B, magnetic free layer 6 may be divided into three parts, and two steps 65 may be formed on side surface 61 of magnetic free layer 6. The rest of the structure may be the same as in the first variation. The number of steps 65 is not limited, and magnetic free layer 6 may be divided into four or more portions to form three or more steps 65. In the third variation shown in FIG. 4C, magnetic free layer 6 may comprise first portion 63 and second portion 64, and the layer structure of laminated body 2 may be similar to the first variation. However, magnetic pinned layer 4, nonmagnetic layer 5, and magnetic free layer 6 may have conical trapezoidal shapes where the diameter of the end surface closer to substrate 3 is larger than the diameter of the end surface farther from substrate 3. In the fourth variation shown in FIG. 4D, side surface 61 of magnetic free layer 6 may be formed continuously and no steps may be formed on side surface 61 of magnetic free layer 6. Because there are no steps between magnetic pinned layer 4, nonmagnetic layer 5, and magnetic free layer 6, the manufacturing process is simplified. In the fifth variation shown in FIG. 4E, magnetic free layer 6 may have first portion 63 and second portion 64, and the layer structure of laminated body 2 is similar to the first variation. The surface of first portion 63 that confronts second portion 64 and the surface of second portion 64 that confronts first portion 63 may have the same diameter, and one angular portion 66 may be formed on side surface 61 of magnetic free layer 6. As in the second variation, magnetic free layer 6 may be divided into three or more portions to form multiple angular portions 66.

Magnetoresistive element 1 of other example embodiments will be described below. The following description will focus on differences from the first example embodiment. Explanation of structure and effects that are the same as those of the first example embodiment will be omitted.

### Second Example Embodiment

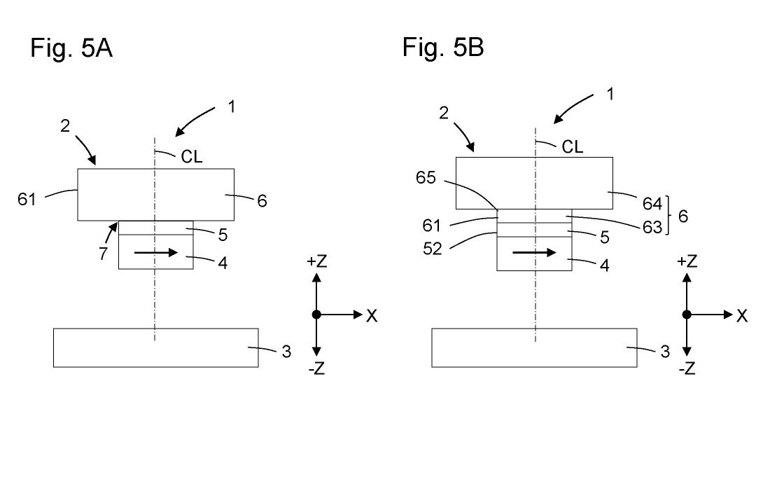

FIG. 5A shows a cross-sectional view of magnetoresistive element 1 in a second example embodiment. Magnetoresistive element 1 may comprise laminated body 2 and substrate 3, and laminated body 2 and substrate 3 may be arranged in the Z-direction. In this example embodiment, magnetic pinned layer 4 may be located between substrate 3 and magnetic free layer 6. The cross-sectional shape of laminated body 2 at any position in the Z-direction may be circular, and magnetic free layer 6, nonmagnetic layer 5, and magnetic pinned layer 4 may be cylinders or disks having common Z-direction central axis CL. Therefore, side surface 61 of magnetic free layer 6 may be formed continuously and no step may be formed on side surface 61 of magnetic free layer 6. The diameter of magnetic free layer 6 may be larger than the diameters of magnetic pinned layer 4 and nonmagnetic layer 5, and step 7 may be formed between nonmagnetic layer 5 and magnetic free layer 6. This example embodiment has the same effects as the first example embodiment because the effect of the distortion of magnetization that occurs in magnetic free layer 6 may be mitigated.

### Variation of the Second Example Embodiment

FIG. 5B shows a cross-sectional view of magnetoresistive element 1 of a variation of the second example embodiment. Magnetic free layer 6 may comprise first portion 63 and second portion 64. The structure of first portion 63 and second portion 64 may be the same as those in the first variation of the first example embodiment. Side surface 52 of nonmagnetic layer 5 and side surface 61 of magnetic free layer 6 may be continuously connected, and at least one (in this variant, one) step 65 may be formed on side surface 61 of magnetic free layer 6.

In this variation, as in the first example embodiment, the soundness of nonmagnetic layer 5 during manufacturing is easily ensured. In the example embodiment shown in FIG. 5A, after depositing the films that will become magnetic pinned layer 4 and nonmagnetic layer 5, a resist mask may be formed on the film that will become nonmagnetic layer 5 to form magnetic pinned layer 4 and nonmagnetic layer 5 in a predetermined shape, following which magnetic free layer 6 may be formed. Nonmagnetic layer 5 may be subjected to reverse sputtering without being covered by a protective film and may suffer degradation. In this variation, the films that will become magnetic pinned layer 4, nonmagnetic layer 5, and first portion 63 of magnetic free layer 6 may each be deposited, following which a resist mask may be formed on the film that will become first portion 63. As a result, nonmagnetic layer 5 may be protected by the film that will become first portion 63 during reverse sputtering. Since first portion 63 of magnetic free layer 6 may have a greater film thickness than nonmagnetic layer 5, the effect of degradation during reverse sputtering may be limited.

### Third Example Embodiment

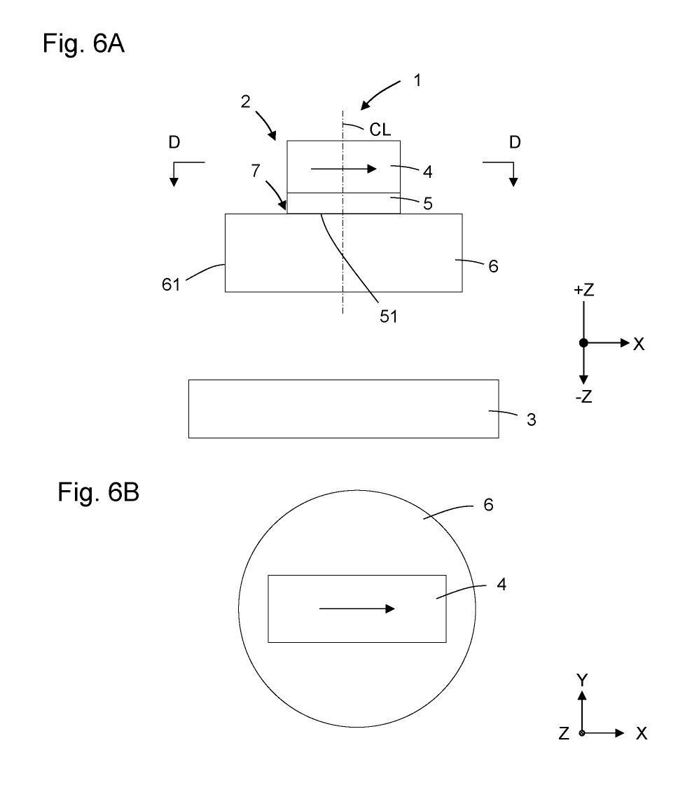

FIG. 6A shows a cross-sectional view of magnetoresistive element 1 of a third example embodiment, and FIG. 6B shows a cross-sectional view taken along D-D line in FIG. 6A. The structure of magnetic free layer 6 may be the same as that in the first example embodiment but may be the same as the structure of magnetic free layer 6 of the variation of the first example embodiment or the second example embodiment. Magnetic pinned layer 4 may be magnetized in the X-direction and may have a rectangular shape whose length in the X-direction is longer than its length in the Y-direction. Since the easy axis of shape anisotropy of magnetic pinned layer 4 may coincide with the magnetization direction of magnetic pinned layer 4 (the X-direction), the resistance of magnetic pinned layer 4 to an external magnetic field may be increased, and the magnetization direction of magnetic pinned layer 4 may be less likely to rotate in the Y-direction. This configuration may enable further improvement of linearity of the output of magnetoresistive element 1. Although not shown in the drawing, the shape of magnetic pinned layer 4 is not limited as long as it has an easy axis of magnetization in the X-direction. As an example, magnetic pinned layer 4 may be elliptical. Nonmagnetic layer 5 may also have a shape whose length in the X-direction is longer than its length in the Y-direction, and may have the same planar shape, the same dimensions, and the same center as magnetic pinned layer 4.

### Fourth Example Embodiment

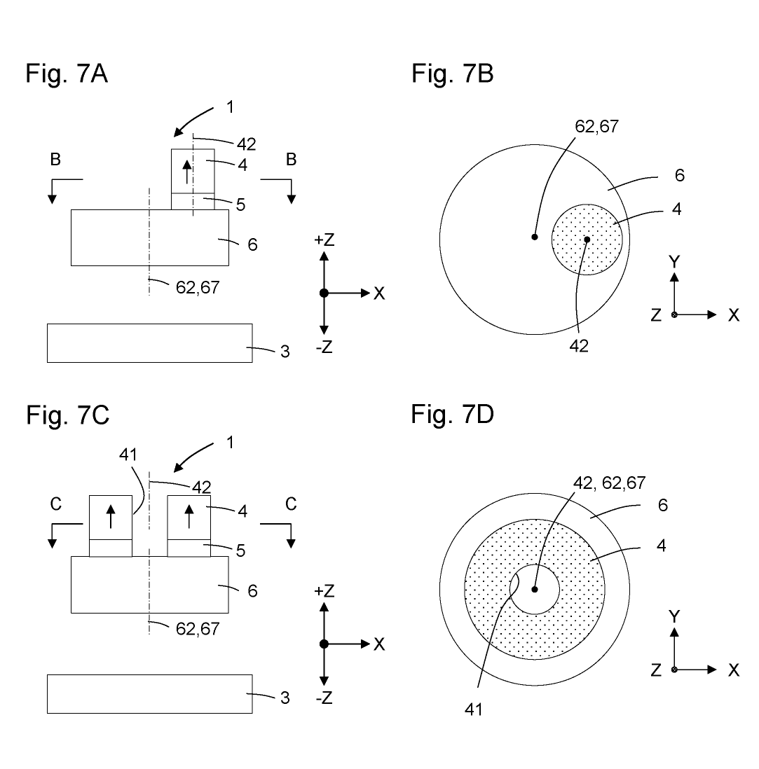

FIG. 7A shows a schematic cross-sectional view of magnetoresistive element 1 of a fourth example embodiment, and FIG. 7B shows a schematic plan view taken along line B-B of FIG. 7A. In this example embodiment, magnetic pinned layer 4 may be magnetized in the Z-direction. In the zero magnetic field state, magnetic free layer 6 may be magnetized in a vortex shape around core 62, but at the position of core 62, magnetic free layer 6 may be magnetized in the Z-direction. However, since both the state of being magnetized in the +Z-direction and the state of being magnetized in the –Z-direction are magnetic stable, the magnetization direction of core 62 can be reversed either from the +Z-direction to the –Z-direction or from the –Z-direction to the +Z-direction depending on the external magnetic field. Once the magnetization direction reverses, the reversed state remains stable and may induce signal offsets or fluctuations. Since the magnetic field generated by magnetic pinned layer 4 can be one of the factors of such an external magnetic field, the offset and fluctuation of the signal can be suppressed by arranging magnetic pinned layer 4 such that core 62 does not overlap with magnetic pinned layer 4 in the Z-direction. Magnetic free layer 6 may have first center line 67 extending in the Z-direction, and magnetic pinned layer 4 may be far from first center line 67 when viewed in the Z-direction. In other words, when viewed in the Z-direction, magnetic pinned layer 4 does not overlap first centerline 67.

FIG. 7C shows a schematic cross-sectional view of magnetoresistive element 1 according to a variation of the fourth example embodiment, and FIG. 7D shows a schematic plan view taken along line C-C of FIG. 7C. Magnetic pinned layer 4 may have through hole 41 passing along first center line 67. In other words, magnetic pinned layer 4 may have a ring-shaped cross-section. Magnetic pinned layer 4 may have second centerline 42 extending in the Z-direction. Second centerline 42 coincides with first centerline 67 but may be separated from first centerline 67. In both structures, core 62 and magnetic pinned layer 4 may not overlap with each other in the Z-direction.

### Fourth Example Embodiment

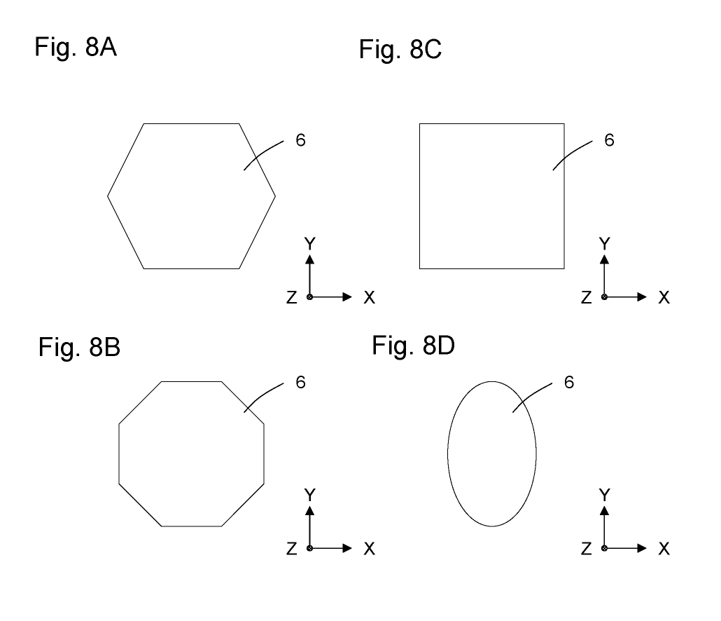

FIGS. 8A–8D are schematic planar views of magnetic free layer 6 of magnetoresistive element 1 of a fifth example embodiment. The vortex-shaped magnetization state may tend to occur in magnetic free layer 6, which is rotationally symmetrical when viewed from the Z-direction. Therefore, magnetic free layer 6 may be not only circular but also polygonal, such as a regular hexagon (see FIG. 8A), an octagon (see FIG. 8B), a square (see FIG. 8C), or an ellipse (see FIG. 8D) when viewed from the Z-direction. Magnetic pinned layer 4 and nonmagnetic layer 5 may also have the same shape as magnetic free layer 6. This example embodiment may also be combined with any of the abovementioned first to fourth example embodiments.

### Sixth Example Embodiment

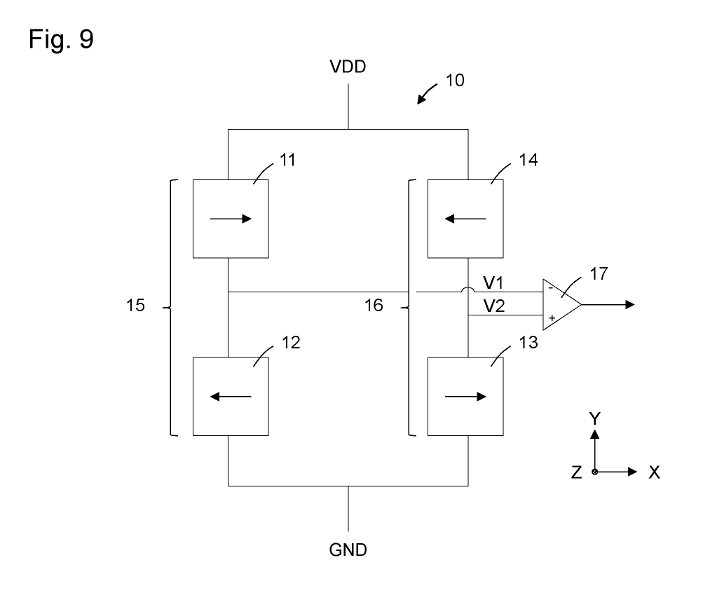

FIG. 9 shows a schematic block diagram of magnetic sensor 10 of a sixth example embodiment. Magnetic sensor 10 of this example embodiment may have first to fourth magnetoresistive elements 11–14. First to fourth magnetoresistive elements 11–14 may be the same as magnetoresistive elements 1 of each of the abovementioned example embodiments. First magnetoresistive element 11 and second magnetoresistive element 12 may be connected in series to constitute first group 15, and third magnetoresistive element 13 and fourth magnetoresistive element 14 may be connected in series to constitute second group 16. One end of each of first group 15 and second group 16 may be connected to power supply VDD and the other ends may be grounded. First magnetoresistive element 11 and fourth magnetoresistive element 14 may be located on the power-supply-VDD side, and second magnetoresistive element 12 and third magnetoresistive element 13 may be located on the ground side (GND). Magnetic sensor 10 may comprise differentiator 17 that calculates the difference between midpoint voltage V1, which is between first magnetoresistive effect element 11 and second magnetoresistive effect element 12, and midpoint voltage V2, which is between third magnetoresistive effect element 13 and fourth magnetoresistive effect element 14. The magnetization directions (indicated by arrows) of magnetic pinned layers 4 of first magnetoresistive element 11 and third magnetoresistive element 13 may be the same direction. The magnetization directions (indicated by arrows) of magnetic pinned layers 4 of second magnetoresistive element 12 and fourth magnetoresistive element 14 may be opposite to the magnetization directions of magnetic pinned layers 4 of first magnetoresistive element 11 and third magnetoresistive element 13.

The voltage drops at each of magnetoresistive element 11–14 may be approximately proportional to the electrical resistances of magnetoresistive elements 11–14. Therefore, when the electrical resistances of first to fourth magnetoresistive elements 11–14 are R1–R4, respectively, midpoint voltage V1 satisfies V1 = R2 / (R1 + R2) x VDD, and midpoint voltage V2 satisfies V2 = R3 / (R3 + R4) x VDD. By obtaining differential output V1–V2 of midpoint voltages V1 and V2 by differentiator 17, the sensitivity may be twice as high as when detecting midpoint voltages V1 and V2. Even if midpoint voltages V1 and V2 are offset, the effect of the offset can be eliminated by detecting the difference.

### Ratio of Diameters of Magnetic free layer 6 and Boundary Surface 51

With regard to circular magnetic free layer 6 and the circular boundary surface 51, the preferred diameter ratio between magnetic free layer 6 and boundary surface 51 was determined by analysis. A model of magnetic sensor 10 shown in FIG. 9 was prepared. Each of magnetoresistive elements 11–14 comprised concentric, cylindrical, or disk-shaped magnetic free layer 6, nonmagnetic layer 5, and magnetic pinned layer 4, as shown in FIGS. 1A and 1B. The diameter of magnetic free layer 6 was 0.5 μm, and the diameters of nonmagnetic layer 5 and magnetic pinned layer 4 (i.e., the diameter φ of boundary surface 51) were 0.5 μm, 0.4 μm, 0.3 μm, 0.2 μm, and 0.1 μm. The diameter of boundary surface 51 of 0.5 μm was a standard value and corresponds to the comparative example. External magnetic field Bx was applied in the X-direction and resistances R1 to R4 of magnetoresistive elements 11–14 were calculated based on micromagnetics simulation results. Resistances R1 and R3 were equal to each other, and resistances R2 and R4 were equal to each other.

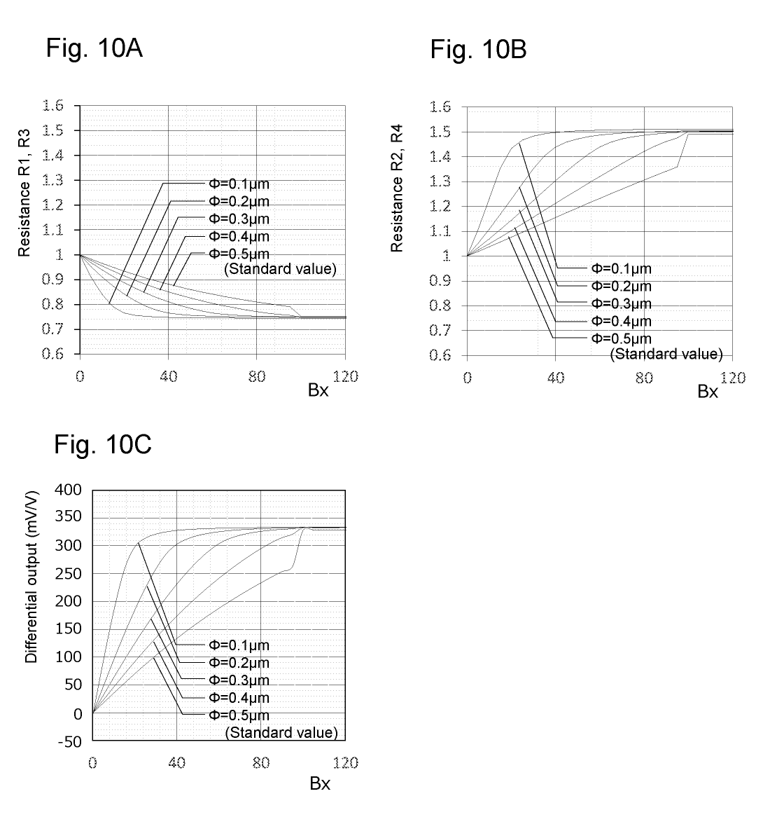

FIG. 10A shows the relationship between external magnetic field Bx and resistances R1 and R3, and FIG. 10B shows the relationship between external magnetic field Bx and resistances R2 and R4. FIG. 10C shows the relationship between external magnetic field Bx and differential output V1–V2. The resistances R1–R4 and differential output V1–V2 on the vertical axis were both standardized values. The differential output V1–V2 was standardized by VDD with the MR ratio of magnetoresistive elements 11–14 as 100%. The MR ratio was obtained by dividing the difference between the maximum and minimum resistances by the minimum resistance for each of magnetoresistive elements 11–14. When diameter φ of boundary surface 51 was 0.5 μm (standard value), a jump in resistance and differential output was observed, but in a range of from 0.4 μm to 0.1 μm, no jump in resistance and differential output was observed.

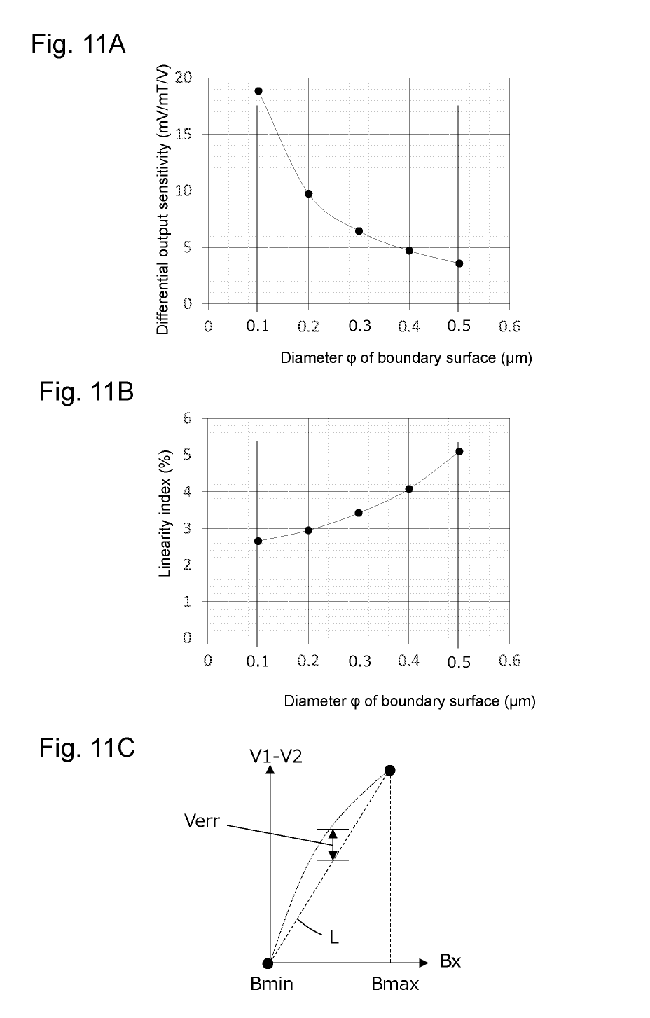

Next, linearity of sensitivity and output of magnetic sensor 10 were determined. FIG. 11A shows the relationship between diameter φ of boundary surface 51 and differential output sensitivity, and FIG. 11B shows the relationship between diameter φ of boundary surface 51 and the linearity index. The differential output sensitivity is a slope (derivative value) of the differential output with respect to the magnetic field at the point of zero magnetic field, standardized by VDD. The linearity index is expressed as the maximum value Verr of the difference between differential output V1–V2 and line L that connects the differential output between the minimum magnetic field Bmin and the maximum magnetic field Bmax in the magnetic field application range, as shown in FIG. 11C. Therefore, the smaller the linearity index, the better the linearity of the output of magnetic sensor 10. Here, the minimum magnetic field Bmin was zero and the maximum magnetic field Bmax was the magnetic field that produced 75% output compared to the output when the magnetization of magnetic free layer 6 was saturated. The sensitivity increased and linearity improved when diameter φ of boundary 51 was small.

Based on these results, when boundary surface 51 of nonmagnetic layer 5 is circular when viewed from the Z-direction, diameter φ of boundary surface 51 should be 80% or less of the diameter of magnetic free layer 6. However, if boundary surface 51 is small, the variation during manufacturing increases. Therefore, diameter φ of boundary surface 51 should be 0.1 μm or more.

### Thickness and Diameter of Magnetic free layer 6

As mentioned above, occurrence or nonoccurrence of a vortex-shaped magnetization state depends on the balance between the exchange energy and the electrostatic energy of magnetic free layer 6, and more specifically, on the thickness and area of magnetic free layer 6. Micromagnetics simulations were performed on a disk simulating magnetic free layer 6 to determine the optimal range of thickness and diameter of the disk in which vortex-shaped magnetization state is likely to occur. The diameters of the disks were 0.3 μm, 0.5 μm, 0.7 μm, 1 μm, 2 μm, 3 μm, 4 μm, 5 μm, 7 μm, and 10 μm, and thicknesses T of disks were 10 nm, 20 nm, 30 nm, 40 nm, 50 nm, 60 nm, 80 nm, and 100 nm. The saturation magnetization of the disks was set to 800 × 10³ A/m and the exchange stiffness coefficient was 1 × e^{–11} J/m for each. Since micromagnetics simulation includes a random element in the analysis, multiple analyses were performed for combinations of a single disk thickness T and diameter to obtain the rate (probability) of vortex-shaped magnetization states.

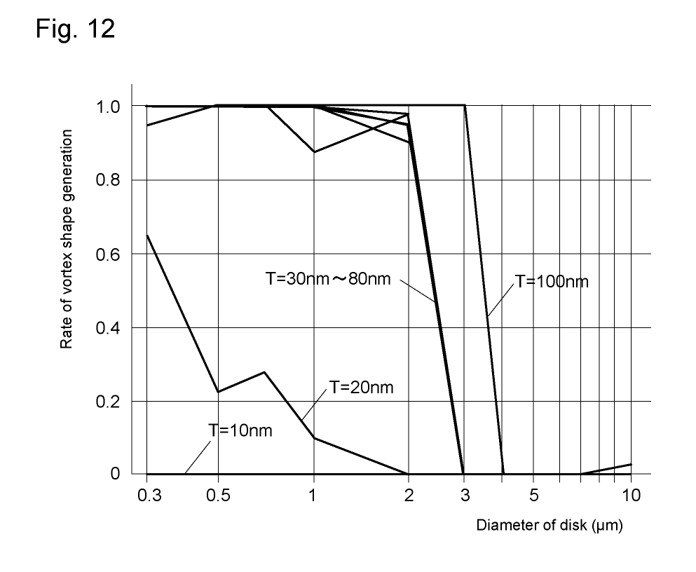

FIG. 12 shows the relationship between thickness T and diameter of the disk and the rate of vortex shape generation. If the diameter of the disk is large, multiple magnetic domains will appear inside the disk and stable vortex shapes will not form. Therefore, the diameter of a disk may be 3 μm or less. If thickness T of a disk is small, the interior of the disk becomes a single magnetic domain and stable vortex shapes cannot be formed. Therefore, thickness T of a disk may be 20 nm or more, and may be 30 nm or more. In the range of T = 30–80 nm, the graphs almost overlap. If the diameter of a disk is less than 0.3 μm, stable formation of a disk in the manufacturing process becomes difficult. If thickness T of a disk exceeds 100 nm, stable formation of the insulating layer on the side of the disk becomes difficult. From the above circumstances, the thickness of magnetic free layer 6 may be between 20 nm and 100 nm, and may be between 30 nm and 100 nm. The diameter of magnetic free layer 6 may be between 0.3 μm and 3 μm.

According to the present disclosure, a magnetoresistive element can be provided that has good linearity of output with respect to an external magnetic field and that comprises a magnetic free layer that is magnetized in a vortex shape in a state in which an external magnetic field is not applied and whose magnetization direction changes upon application of an external magnetic field.

Although preferred example embodiments of the present disclosure have been shown and described in detail, it is to be understood that various changes and modifications are possible without departing from the intent or scope of the appended claims.

### REFERENCE NUMERALS

1 magnetoresistive element

2 laminated body

3 substrate

4 magnetic pinned layer

5 nonmagnetic layer

6 magnetic free layer

7 step

10 magnetic sensor

41 through hole

42 second centerline

51 boundary surface

53 outer periphery of boundary surface

63 first portion

64 second portion

65 step

66 corner portion

67 first centerline

Z first direction

X second direction

Y third direction

1. A magnetoresistive element comprising
a magnetic free layer that is magnetized in a vortex shape in a state in which an external magnetic field is not applied, and whose magnetization direction changes upon application of an external magnetic field,
a magnetic pinned layer whose magnetization direction is pinned with respect to an external magnetic field, and
a nonmagnetic layer located between the magnetic free layer and the magnetic pinned layer, wherein
the magnetic free layer, the magnetic pinned layer, and the nonmagnetic layer are arranged in a first direction,
the nonmagnetic layer has a boundary surface that is in contact with the magnetic free layer, and
a portion of the magnetic free layer is outside an outer periphery of the boundary surface as viewed from the first direction.

2. The magnetoresistive element according to claim 1, wherein a step is formed between the nonmagnetic layer and the magnetic free layer.

3. The magnetoresistive element according to claim 1, wherein the side surface of the nonmagnetic layer and the side surface of the magnetic free layer are continuously connected.

4. The magnetoresistive element according to claim 1, wherein at least one step is formed on a side surface of the magnetic free layer.

5. The magnetoresistive element according to claim 1, wherein the magnetic free layer comprises a first portion and a second portion that are aligned in the first direction, and the first portion is in contact with the nonmagnetic layer and has smaller area and smaller thickness than the second portion.

6. The magnetoresistive element according to claim 1, wherein the side surface of the magnetic free layer is continuously formed.

7. The magnetoresistive element according to claim 6, wherein at least one angle is formed on a side surface of the magnetic free layer.

8. The magnetoresistive element according to claim 1, wherein the magnetic pinned layer is magnetized in a second direction that is orthogonal to the first direction, and the length of the magnetic pinned layer in the second direction is longer than its length in a third direction that is orthogonal to the first and second directions.

9. The magnetoresistive element according to claim 1, wherein
the magnetic pinned layer is magnetized in the first direction,
the magnetic free layer has a first centerline that is parallel to the first direction, and
the magnetic pinned layer is separate from the first centerline as viewed from the first direction.

10. The magnetoresistive element according to claim 9, wherein the magnetic pinned layer and the nonmagnetic layer have second centerlines that are parallel to the first centerline.

11. The magnetoresistive element according to claim 10, wherein the magnetic pinned layer has a through hole through which the first centerline passes.

12. The magnetoresistive element according to claim 1, wherein the magnetic free layer is rotationally symmetric as viewed from the first direction.

13. The magnetoresistive element according to claim 12, wherein the magnetic free layer is circular as viewed from the first direction.

14. The magnetoresistive element according to claim 13, wherein the magnetic free layer has a thickness between 20 nm and 100 nm and has a diameter between 0.3 μm and 3 μm.

15. The magnetoresistive element according to claim 13, wherein the boundary surface is circular as viewed from the first direction, and the diameter of the boundary surface is 0.1 μm or more and 80% or less of the diameter of the magnetic free layer.

16. The magnetoresistive element according to claim 1, comprising a laminated body that comprises the magnetic free layer, the magnetic pinned layer, and the nonmagnetic layer, and a substrate,
wherein the laminated body and the substrate are aligned in the first direction, and
wherein the magnetic free layer is located between the substrate and the magnetic pinned layer.

17. The magnetoresistive element according to claim 1, comprising a laminated body that comprises the magnetic free layer, the magnetic pinned layer, and the nonmagnetic layer, and a substrate,
wherein the laminated body and the substrate are aligned in the first direction, and
wherein the magnetic pinned layer is located between the substrate and the magnetic free layer.

18. A magnetic sensor comprising the magnetoresistive element according to claim 1.
